(19) United States
(12) Patent Application Publication
(10) Pub. No.: US 2026/0344231 A1
(43) Pub. Date: Oct. 29, 2026

(54) DISPLAY DEVICE AND ELECTRONIC DEVICE INCLUDING THE SAME

(71) Applicant: Samsung Display Co., Ltd., Yongin-si (KR)

(72) Inventor: Taekon KIM, Yongin-si (KR)

(73) Assignee: Samsung Display Co., Ltd., Yongin-si (KR)

(21) Appl. No.: 19/374,767

(22) Filed: Oct. 30, 2025

(30) Foreign Application Priority Data
Apr. 24, 2025 (KR) 10-2025-0053655

(51) Int. Cl. H10K 59/131; G09G 3/3266; H10K 59/88

(52) U.S. Cl. CPC H10K 59/1315; G09G 3/3266; H10K 59/88; G09G 2330/06

(57) ABSTRACT

A display device includes: a substrate including a display area having an edge which includes a corner portion having a rounded shape in a plan view and a peripheral area adjacent to the display area; pixels in the display area and arranged in a stepwise manner in an area adjacent to the corner portion; a scan driver in the peripheral area; a bus line part in the peripheral area, extending between the scan driver and the corner portion in the plan view, and configured to have a constant voltage applied thereto; a bus connection line on the substrate, connected to the bus line part, adjacent to the corner portion, and configured to transmit the constant voltage to the pixels; and a dummy line in the peripheral area on the substrate and spaced further from the corner portion than the bus connection line in the plan view.

### CROSS-REFERENCE TO RELATED APPLICATION

This application claims priority under 35 USC § 119 to Korean Patent Application No. 10-2025-0053655, filed on Apr. 24, 2025, in the Korean Intellectual Property Office, the content of which is herein incorporated by reference in its entirety.

### BACKGROUND

### 1. Field

The present disclosure relates generally to a display device. More particularly, the present disclosure relates to a display device and an electronic device including the display device.

### 2. Description of the Related Art

With the development of information technology, the importance of a display device has been highlighted, where the display device may be a connection medium between a user and information. For example, the use of display devices, such as liquid crystal display (LCD) device, organic light emitting diode (OLED) display device, plasma display panel (PDP) device, quantum dot display device or the like is increasing.

A display device may include pixels that emit light and drivers that transmit a driving signal to the pixels. Each of the pixels may include a light-emitting element and a pixel driving circuit that may be connected to the light-emitting element and may generate a driving current. The electrostatic discharge (ESD) may occur in a line that transmits the driving signal to the pixels. When a pulse potential due to the electrostatic discharge flows into the pixels, a malfunction may occur in the pixel driving circuit. Research is being conducted to protect the pixels from the electrostatic discharge.

### SUMMARY

Embodiments provide a display device with improved display quality.

Embodiments provide an electronic device including the display device.

A display device according to an embodiment of the present disclosure may include a substrate comprising a display area and a peripheral area adjacent to the display area, the display area having an edge which comprises a corner portion having a rounded shape in a plan view; a plurality of pixels in the display area on the substrate and arranged in a stepwise manner in an area adjacent to the corner portion; a scan driver in the peripheral area on the substrate; a bus line part in the peripheral area on the substrate, wherein the bus line part may extend between the scan driver and the corner portion in the plan view, and the bus line part may be configured to have a constant voltage applied thereto; a bus connection line on the substrate, wherein the bus connection line may be connected to the bus line part, the bus connection line may be adjacent to the corner portion, and the bus connection line may be configured to transmit the constant voltage to the plurality of pixels; and a dummy line in the peripheral area on the substrate, wherein the dummy line may be spaced further from the corner portion than the bus connection line in the plan view.

In an embodiment, a length of the dummy line may be greater than a length of the bus connection line.

In an embodiment, the edge of the display area may further include a first side extending in a first direction and a second side extending in a second direction. The second direction may intersect the first direction. The corner portion may connect the first side and the second side.

In an embodiment, the dummy line may extend parallel to the second side.

In an embodiment, the dummy line may partially overlap the bus line part in the plan view.

In an embodiment, the display device may further include a scan connection line on the substrate, wherein the scan connection line may be connected to the scan driver and the scan connection line may be configured to transmit a scan signal to the plurality of pixels. The dummy line may partially overlap the scan connection line in the plan view.

In an embodiment, the bus line part may include a first bus line configured to have a driving voltage applied thereto. The bus connection line may include a first bus connection line connected to the first bus line and the first bus connection line may be configured to transmit the driving voltage to the plurality of pixels.

In an embodiment, the display device may further include a first active pattern above the substrate, a first gate electrode above the first active pattern, a capacitor electrode above the first gate electrode, a second gate electrode above the capacitor electrode, and a source electrode and a drain electrode above the first active pattern.

In an embodiment, the dummy line may be under the source electrode and the drain electrode.

In an embodiment, the dummy line and the second gate electrode may be in a same layer.

In an embodiment, the first bus line, the source electrode, and the drain electrode may be in a same layer. The first bus connection line and a second gate electrode may be in a same layer.

In an embodiment, a first gate electrode may be on the first active pattern; a second gate electrode may be on the substrate; and the dummy line and the second gate electrode may be in a same layer.

A display device according to an embodiment of the present disclosure may include: a substrate comprising a display area and a peripheral area adjacent to the display area, the display area having an edge which comprises a first side extending in a first direction, a second side extending in a second direction, and a corner portion which connects the first side and the second side and has a rounded shape in a plan view, the second direction intersecting the first direction; a plurality of pixels in the display area on the substrate and arranged in a stepwise manner in an area adjacent to the corner portion; a scan driver in the peripheral area on the substrate; a bus line part in the peripheral area on the substrate, wherein the bus line part may extend between the scan driver and the corner portion in the plan view, and the bus line part may be configured to have a constant voltage applied thereto; a bus connection line on the substrate, wherein the bus connection line may be connected to the bus line part, the bus connection line may extend in the second direction, and the bus connection line may be configured to transmit the constant voltage to the plurality of pixels; and a dummy line in the peripheral area on the substrate and positioned closer to the scan driver than the bus connection line in the plan view.

In an embodiment, a length of the dummy line may be greater than a length of the bus connection line.

In an embodiment, the dummy line may be adjacent to the second side in the first direction.

In an embodiment, the bus connection line may be adjacent to the corner portion and the bus connection line may be configured to transmit the constant voltage to the plurality of pixels arranged in the stepwise manner in the area adjacent to the corner portion.

In an embodiment, the dummy line may partially overlap the bus line part in the plan view.

In an embodiment, the display device may further include a scan connection line on the substrate, wherein the scan connection line may be connected to the scan driver, and the scan connection line may be configured to transmit a scan signal to the plurality of pixels. The dummy line may partially overlap the scan connection line in the plan view.

In an embodiment, the bus line part may include a first bus line configured to have a driving voltage applied thereto. The bus connection line may include a first bus connection line. The first bus connection line may be connected to the first bus line. The first bus connection line may be configured to transmit the driving voltage to the plurality of pixels.

An electronic device according to an embodiment of the present disclosure may include a display device comprising a plurality of pixels; and a processor configured to transmit an image data signal and an input control signal to the display device. The display device may include a substrate, the plurality of pixels, a scan driver, a bus line part, a bus connection line, and a dummy line. The substrate may include a display area and a peripheral area adjacent to the display area. The display area may have an edge which comprises a corner portion having a rounded shape in a plan view. The plurality of pixels may be in the display area on the substrate and may be arranged in a stepwise manner in an area adjacent to the corner portion. The scan driver may be in the peripheral area on the substrate. The bus line part may be in the peripheral area on the substrate. The bus line part may extend between the scan driver and the corner portion in the plan view. The bus line part may be configured to have a constant voltage applied thereto. The bus connection line may be on the substrate. The bus connection line may be connected to the bus line part. The bus connection line may be adjacent to the corner portion. The bus connection line may be configured to transmit the constant voltage to the plurality of pixels. The dummy line may be in the peripheral area on the substrate. The dummy line may be spaced further from the corner portion than the bus connection line in the plan view.

A display device according to an embodiment of the present disclosure may include a substrate including a display area that includes a corner portion having a rounded shape in a plan view, pixels disposed in a stepwise manner in an area adjacent to the corner portion, a bus connection line adjacent to the corner portion and configured to transmit a constant voltage to the pixels, and a dummy line spaced further from the corner portion than the bus connection line in a plan view.

The dummy line may induce a pulse potential caused by electrostatic discharge generated in the bus connection line to flow toward the dummy line. In other words, the pulse potential caused by the electrostatic discharge generated in the bus connection line may flow into the dummy line, and the amount of the pulse potential flowing into the pixels may be reduced. Accordingly, a malfunction of a pixel driving circuit caused by the pulse potential may be reduced, and the display quality of the display device may be improved.

In an embodiment, a length of the dummy line may be greater than a length of the bus connection line. Accordingly, the pulse potential may be further flow into the dummy line, and the amount of the pulse potential flowing into the pixels may be further reduced.

### BRIEF DESCRIPTION OF THE DRAWINGS

Illustrative, non-limiting embodiments will be more clearly understood from the following detailed description in conjunction with the accompanying drawings.

FIG. 1 is a block diagram illustrating a display device according to an embodiment of the present disclosure.

FIG. 2 is a plan view illustrating the display device of FIG. 1.

FIG. 3 is a circuit diagram illustrating an example of a circuit structure of a pixel included in the display device of FIG. 1.

FIG. 4 is a cross-sectional view taken along the line I-T of FIG. 2.

FIG. 5 is an enlarged plan view of the area A of FIG. 2.

FIG. 6 is an enlarged plan view of the area B of FIG. 2.

FIG. 7 is an enlarged plan view of the area C of FIG. 6.

FIG. 8 is a cross-sectional view taken along the line II-IT′ of FIG. 7.

FIG. 9 is a block diagram illustrating an electronic device according to an embodiment of the present disclosure.

FIG. 10 is a schematic view of an electronic device according to various embodiments.

### DETAILED DESCRIPTION OF THE EMBODIMENTS

Hereinafter, embodiments of the present disclosure will be described in detail with reference to the accompanying drawings. The same reference numerals are used for the same components in the drawings, and redundant descriptions of the same components will be omitted.

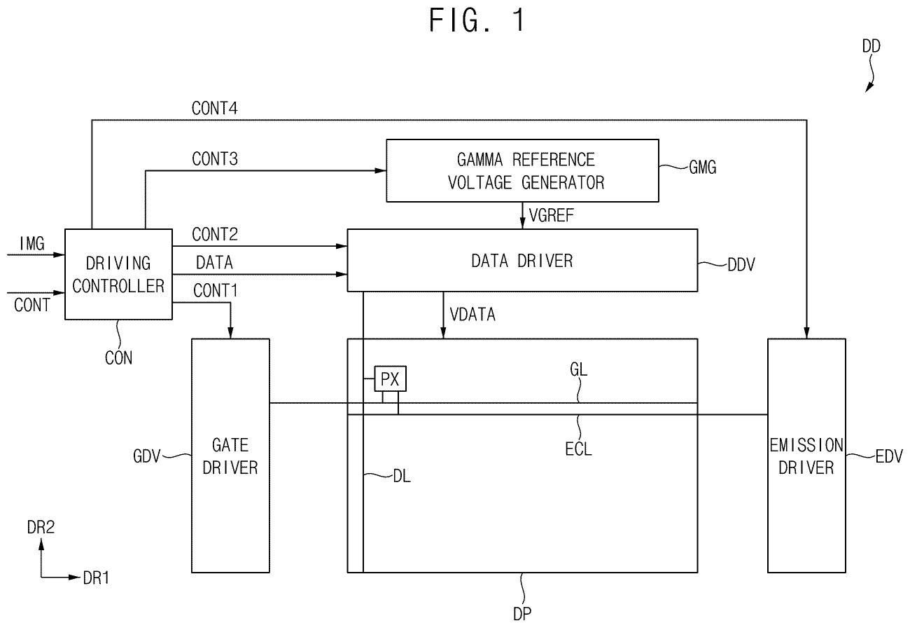

FIG. 1 is a block diagram illustrating a display device according to an embodiment of the present disclosure.

Referring to FIG. 1, a display device DD according to an embodiment of the present disclosure may include a display panel DP and a panel driver that drives the display panel DP. The panel driver may include a driving controller CON, a gate driver GDV, a gamma reference voltage generator GMG, a data driver DDV, and an emission driver EDV.

For example, the driving controller CON and the data driver DDV may be integrally formed. A driving module in which the driving controller CON and the data driver DDV are integrally formed may be referred to as a timing controller embedded data driver (TED).

The display panel DP may include gate lines GL, emission lines ECL, data lines DL, and pixels PX. The pixels PX may be electrically connected to the gate lines GL, the emission lines ECL, and the data lines DL. Each of the pixels PX may generate light in response to a driving signal. For example, each of the gate lines GL may extend in a first direction DR1, and each of the emission lines ECL may extend in the first direction DR1. Each of the data lines DL may extend in a second direction DR2 intersecting the first direction DR1. For example, the first direction DR1 and the second direction DR2 may be perpendicular to each other.

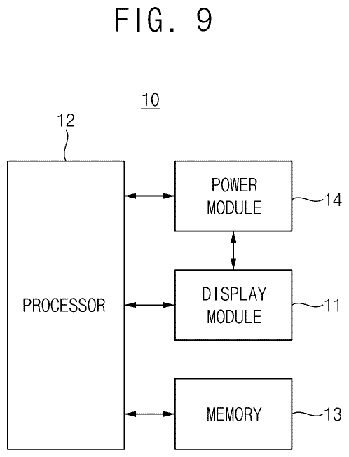

The driving controller CON may receive an image data signal IMG and an input control signal CONT from an external device (e.g., a processor 12 of FIG. 9). For example, the image data signal IMG may include red image data, green image data, and blue image data. In an embodiment, the image data signal IMG may further include white image data. The input control signal CONT may include a vertical synchronization signal, a horizontal synchronization signal, a data enable signal, a master clock signal, or the like.

The driving controller CON may generate a first control signal CONT1, a second control signal CONT2, a third control signal CONT3, a fourth control signal CONT4, and a data signal DATA based on the image data signal IMG and the input control signal CONT.

The driving controller CON may output the first control signal CONT1 to the gate driver GDV. The first control signal CONT1 may include a vertical start signal and a gate clock signal. The driving controller CON may output the second control signal CONT2 and the data signal DATA to the data driver DDV. The second control signal CONT2 may include a horizontal start signal and a load signal. The driving controller CON may output the third control signal CONT3 to the gamma reference voltage generator GMG. The driving controller CON may output the fourth control signal CONT4 to the emission driver EDV.

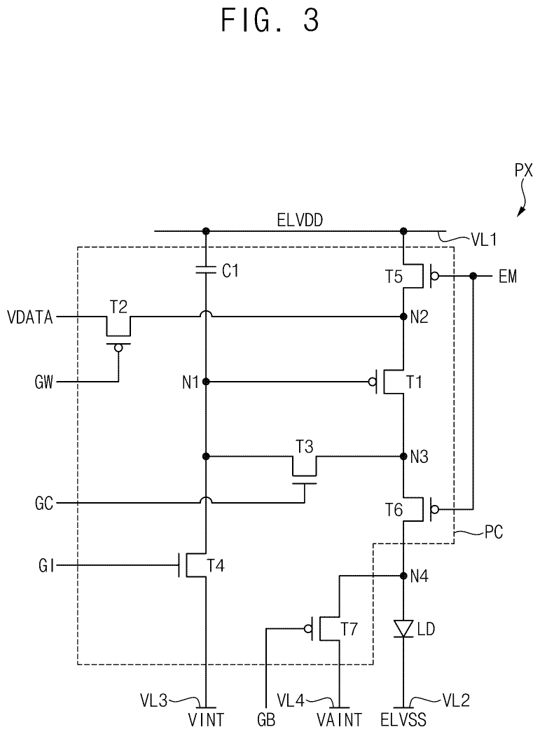

The gate driver GDV may generate gate signals in response to the first control signal CONT1. The gate driver GDV may output the gate signals to the gate lines GL. In an embodiment, the gate signals may include first to fourth gate signals GW, GC, GI, and GB illustrated in FIG. 3. However, the present disclosure is not necessarily limited thereto.

The gamma reference voltage generator GMG may generate a gamma reference voltage VGREF in response to the third control signal CONT3. The gamma reference voltage generator GMG may provide the gamma reference voltage VGREF to the data driver DDV. For example, the gamma reference voltage generator GMG may be disposed in the driving controller CON, or may be disposed in the data driver DDV.

The data driver DDV may receive the second control signal CONT2 and the data signal DATA from the driving controller CON, and may receive the gamma reference voltage VGREF from the gamma reference voltage generator GMG. The data driver DDV may convert the data signal DATA into an analog form of a data voltage VDATA using the gamma reference voltage VGREF. The data driver DDV may output the data voltage VDATA to the data lines DL.

The emission driver EDV may generate emission signals in response to the fourth control signal CONT4. The emission driver EDV may output the emission signals to the emission lines ECL. In an embodiment, the emission signals may include an emission control signal EM illustrated in FIG. 3. However, the present disclosure is not necessarily limited thereto.

In FIG. 1, for convenience of description, the gate driver GDV is illustrated as being disposed at a first side of the display panel DP and the emission driver EDV is illustrated as being disposed at a second side opposite to the first side of the display panel DP, but the present disclosure is not necessarily limited thereto. For example, both the gate driver GDV and the emission driver EDV may be disposed at the first side of the display panel DP. For another example, both the gate driver GDV and the emission driver EDV may be disposed at opposite sides of the display panel DP. For another example, the gate driver GDV and the emission driver EDV may be integrally formed.

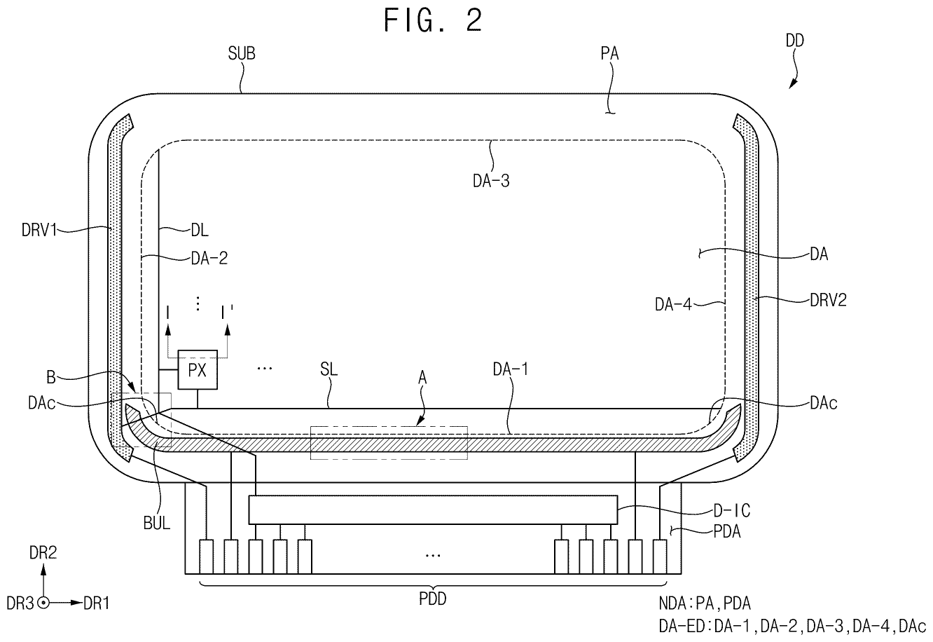

FIG. 2 is a plan view illustrating the display device of FIG. 1.

In this specification, a plane may be defined by the first direction DR1 and the second direction DR2 intersecting the first direction DR1. A direction normal to the plane may be a third direction DR3. In other words, the third direction DR3 may be perpendicular to each of the first direction DR1 and the second direction DR2. The third direction DR3 may be a thickness direction of the display device DD. As used herein the “plan view” is a view in the third direction DR3.

Referring to FIGS. 1 and 2, the display device DD may be a device that is activated in response to an electrical signal. For example, the display device DD may be a medium- to large-sized display device used in medium- to large-sized electronic devices such as a laptop, a tablet PC, a television, a computer monitor, an in-vehicle monitor, and an exterior billboard. However, the present disclosure is not necessarily limited thereto, and the display device DD may be a small display device used in small electronic devices such as a smartphone, a cell phone, a smart watch, a game console, and a camera.

The display device DD may include the display panel DP, a first scan driver DRV1, a second scan driver DRV2, a bus line part BUL, and a driving chip D-IC, and the display panel DP may include a substrate SUB, the pixels PX, a scan line SL, and the data line DL.

The substrate SUB may form a base of the display device DD. The substrate SUB may include a transparent material or an opaque material. In an embodiment, examples of materials that may be used as the substrate SUB may include glass, quartz, silicon, polymer, or the like. These may be used alone or in combination with each other. The substrate may include a display area DA and a non-display area NDA.

The display area DA may be an area that displays an image by generating light or adjusting the transmittance of light provided from an external light source. The pixels PX may be disposed in the display area DA on the substrate SUB. The pixels PX may emit light in response to a driving signal. The pixels PX may be electrically connected to the scan line SL and the data line DL. In this case, the scan line SL may correspond to the gate line GL or the emission line ECL of FIG. 1. For example, the pixels PX may be disposed in a matrix form along the first direction DR1 and the second direction DR2.

Each of the pixels PX may include a plurality of sub-pixels. For example, each of the pixels PX may include a first sub-pixel, a second sub-pixel, and a third sub-pixel. Each of the first to third sub-pixels may include a light-emitting element and a pixel driving circuit connected to the light-emitting element. The light-emitting element may emit light. In an embodiment, the first to third sub-pixels may emit light of different wavelength bands. That is, the first to third sub-pixels may emit light of different colors. For example, the first sub-pixel may emit red light, the second sub-pixel may emit green light, and the third sub-pixel may emit blue light, but the present disclosure is not necessarily limited thereto.

The non-display area NDA may be an area that does not display an image. Drivers for driving the pixels PX may be disposed in the non-display area NDA. The non-display area NDA may be adjacent to the display area DA. The non-display area NDA may include a peripheral area PA and a pad area PDA. The peripheral area PA may be positioned around the display area DA. The peripheral area PA may surround at least a portion of the display area DA in a plan view. For example, the peripheral area PA may entirely surround the display area DA in a plan view. The pad area PDA may be positioned at one side of the display area DA. The pad area PDA may be spaced apart from the display area DA by the peripheral area PA. For example, the pad area PDA and the display area DA may be spaced apart from each other in the second direction DR2. A plurality of pads PDD may be disposed in the pad area PDA on the substrate SUB. The pads PDD may be connected to the first scan driver DRV1, the second scan driver DRV2, the bus line part BUL, and the driving chip D-IC.

The first scan driver DRV1 and the second scan driver DRV2 may be disposed in the peripheral area PA on the substrate SUB. The first scan driver DRV1 and the second scan driver DRV2 may be spaced apart from each other. For example, the first scan driver DRV1 may be disposed in the peripheral area PA adjacent to a left side of the display area DA, and the second scan driver DRV2 may be disposed in the peripheral area PA adjacent to a right side of the display area DA.

Each of the first scan driver DRV1 and the second scan driver DRV2 may correspond to the gate driver GDV or the emission driver EDV of FIG. 1. For example, each of the first scan driver DRV1 and the second scan driver DRV2 may output the gate signal to the scan line SL. The gate signal may be applied to the pixels PX through the scan line SL. For example, each of the first scan driver DRV1 and the second scan driver DRV2 may output the emission signal to the scan line SL. The emission signal may be applied to the pixels PX through the scan line SL. In an embodiment, the first scan driver DRV1 and the second scan driver DRV2 may be disposed at opposite sides of the display area DA in the first direction DR1, but the present disclosure is not necessarily limited thereto. In an embodiment, any one of the first scan driver DRV1 and the second scan driver DRV2 may be omitted.

The driving chip D-IC may be disposed in the pad area PDA on the substrate SUB. The driving chip D-IC may correspond to the data driver DDV of FIG. 1. That is, the driving chip D-IC may output the data voltage to the data line DL. The data voltage may be applied to the pixels PX through the data line DL.

In an embodiment, the driving chip D-IC may be mounted on the substrate SUB. However, the present disclosure is not necessarily limited thereto, and the driving chip D-IC may be disposed on a flexible film bonded to the substrate SUB in the form of chip on film (COF).

The bus line part BUL may be disposed in the peripheral area PA on the substrate SUB. For example, the bus line part BUL may be disposed in the peripheral area PA adjacent to a lower side of the display area DA. In addition, the bus line part BUL may partially surround the left side of the display area DA and the right side of the display area DA in a plan view. For example, the bus line part BUL may be disposed between the display area DA and the driving chip D-IC in a plan view.

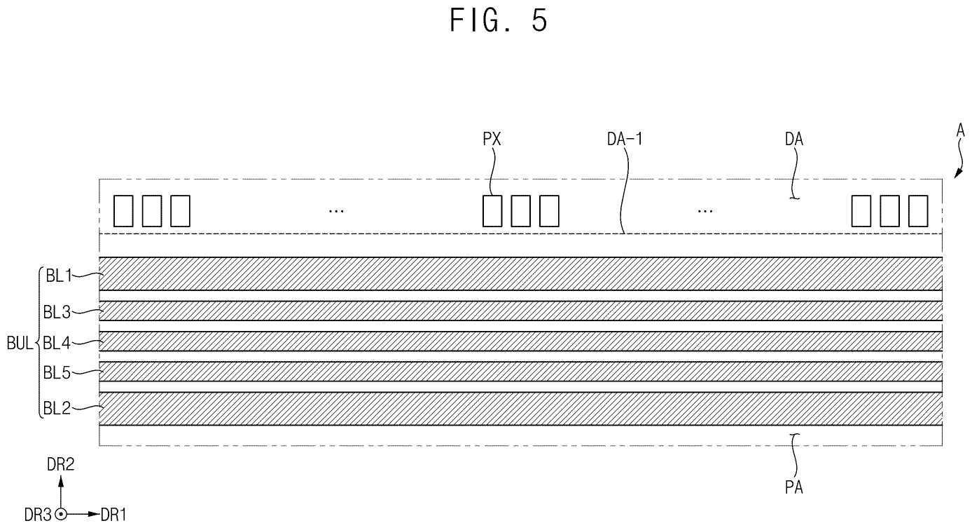

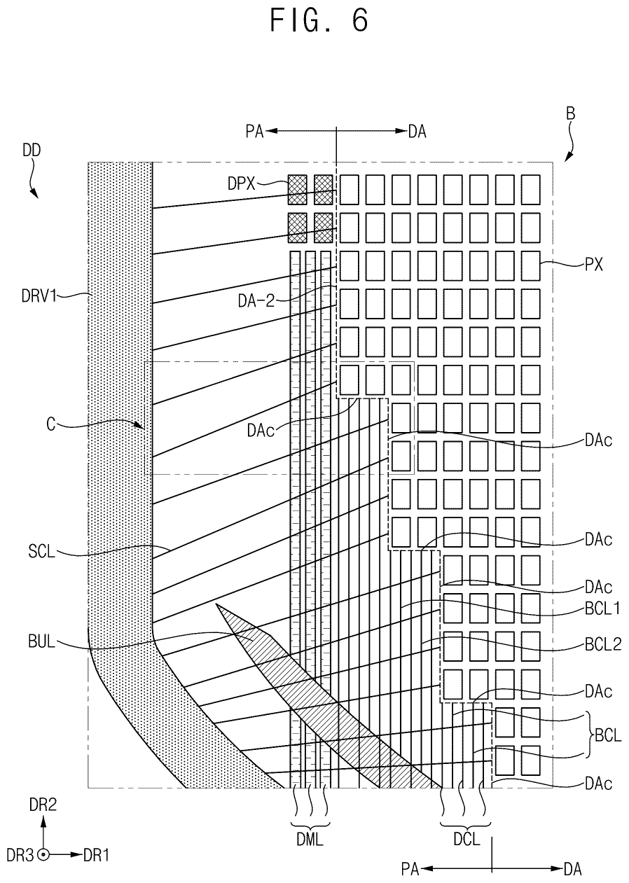

The bus line part BUL may include a plurality of bus lines to which a constant voltage is applied. The bus line part BUL may transmit the constant voltage to the pixels PX through bus connection lines (BCL, see FIG. 6). In an embodiment, the bus line part BUL may include a first bus line to which a driving voltage (ELVDD, see FIG. 3) is applied, a second bus line to which a common voltage (ELVSS, see FIG. 3) is applied, a third bus line to which a first initialization voltage (VINT, see FIG. 3) is applied, and a fourth bus line and a fifth bus line to which a second initialization voltage (VAINT, see FIG. 3) is applied. A detailed description thereof will be described below with reference to FIG. 5.

In an embodiment, the display area DA may have a planar shape of a rectangle with rounded corners. For example, the display area DA may have a planar shape of a rectangle with rounded corners having a long side extending in the first direction DR1 and a short side extending in the second direction DR2, but the present disclosure is not necessarily limited thereto. For example, the display area DA may have a planar shape of a rectangular shape with rounded corners having a short side extending in the first direction DR1 and a long side extending in the second direction DR2. For another example, the display area DA may have a circular planar shape or an elliptical planar shape.

In an embodiment, the display area DA may have an edge DA-ED including first to fourth sides DA-1, DA-2, DA-3, and DA-4) extending in a straight line in a plan view and a corner portion DAc having a rounded shape in a plan view. The first side DA-1 and the third side DA-3 may face each other and extend in parallel in the first direction DR1. The second side DA-2 and the fourth side DA-4 may face each other and extend in parallel in the second direction DR2. In an embodiment, a length of the first side DA-1 may be greater than a length of the second side DA-2, but the present disclosure is not necessarily limited thereto.

The corner portion DAc may be positioned between the first side DA-1 and the second side DA-2, between the second side DA-2 and the third side DA-3, between the third side DA-3 and the fourth side DA-4, and between the first side DA-1 and the fourth side DA-4. The corner portion DAc may connect the first side DA-1 and the second side DA-2. The corner portion DAc may connect the second side DA-2 and the third side DA-3. The corner portion DAc may connect the third side DA-3 and the fourth side DA-4. The corner portion DAc may connect the first side DA-1 and the fourth side DA-4.

An end of each of the first scan driver DRV1 and the second scan driver DRV2 may extend along the corner portion DAc. The end of each of the first scan driver DRV1 and the second scan driver DRV2 may have a rounded shape. An end of the bus line part BUL may extend along the corner portion DAc. That is, in order to provide the constant voltage to the pixels PX disposed in an area adjacent to the corner portion DAc, the end of the bus line part BUL may extend between the first scan driver DRV1 and the display area DA or between the second scan driver DRV2 and the display area DA along the corner portion DAc.

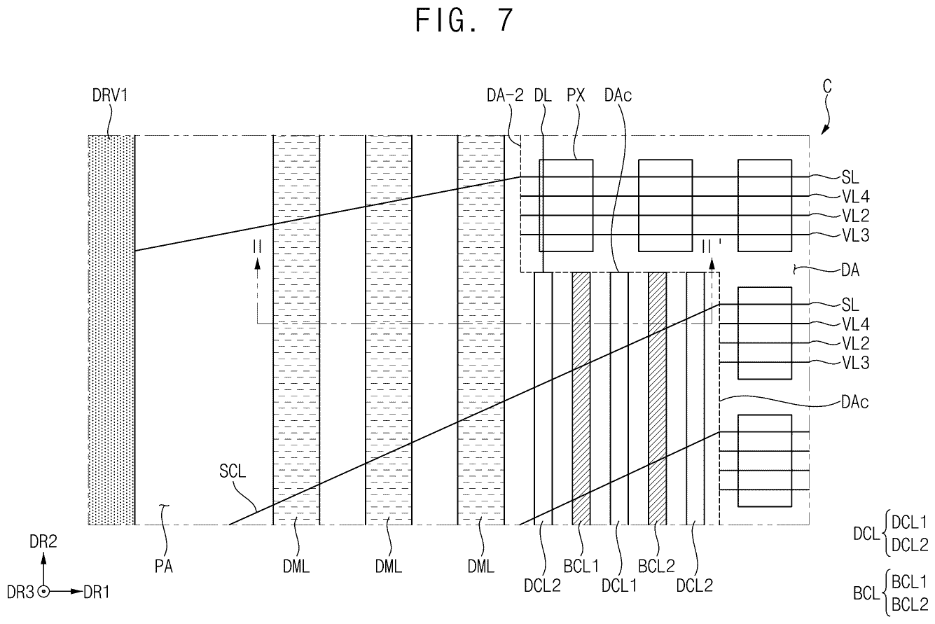

In an embodiment, in an area adjacent to the corner portion DAc, the pixels PX may be arranged in a stepwise manner. A detailed description thereof will be described below with reference to FIGS. 6 and 7.

FIG. 3 is a circuit diagram illustrating an example of a circuit structure of a pixel included in the display device of FIG. 1. For example, FIG. 3 may be a circuit diagram of any one of the first to third sub-pixels included in the pixel PX.

Referring to FIG. 3, the pixel PX may include the first to third sub-pixels, and the first to third sub-pixels may have substantially the same circuit structure as each other. Each of the first to third sub-pixels may include a light-emitting element LD and a pixel driving circuit PC connected to the light-emitting element LD. The pixel driving circuit PC may generate a driving current, and the light-emitting element LD may generate light based on the driving current.

The pixel driving circuit PC may include at least one transistor and at least one capacitor. In an embodiment, the pixel driving circuit PC may include first to seventh transistors T1, T2, T3, T4, T5, T6, and T7 and a first capacitor C1. Each of the first to seventh transistors T1, T2, T3, T4, T5, T6, and T7 may be a metal oxide semiconductor field effect transistor (MOSFET) formed by a semiconductor process.

In FIG. 3, the first transistor T1, the second transistor T2, the fifth transistor T5, the sixth transistor T6, and the seventh transistor T7 are illustrated as p-type transistors, and the third transistor T3 and the fourth transistor T4 are illustrated as n-type transistors, but the present disclosure is not necessarily limited thereto. For example, the first to seventh transistors T1, T2, T3, T4, T5, T6, and T7 may all be p-type transistors. For example, the first to seventh transistors T1, T2, T3, T4, T5, T6, and T7 may all be n-type transistors.

When the pixel PX includes the n-type transistor and the p-type transistor, an active pattern of the n-type transistor may include an oxide semiconductor material, and an active pattern of the p-type transistor may include a silicon semiconductor material. However, the present disclosure is not necessarily limited thereto, and both the active pattern of the n-type transistor and the active pattern of the p-type transistor may include a silicon semiconductor material.

The pixel driving circuit PC may be connected to first to fourth voltage lines VL1, VL2, VL3, and VL4. The first voltage line VL1 may transmit a driving voltage ELVDD having a relatively high voltage level. The second voltage line VL2 may transmit a common voltage ELVSS having a relatively low voltage level. The third voltage line VL3 may transmit a first initialization voltage VINT. The fourth voltage line VL4 may transmit a second initialization voltage VAINT.

The first transistor T1 may include a gate electrode, a first electrode, and a second electrode. The gate electrode of the first transistor T1 may be connected to a first node N1. The first electrode of the first transistor T1 may be connected to a second node N2. The second electrode of the first transistor T1 may be connected to a third node N3. The first transistor T1 may provide a driving current to the light-emitting element LD. For example, the first transistor T1 may be referred to as a driving transistor.

The second transistor T2 may include a gate electrode, a first electrode, and a second electrode. The gate electrode of the second transistor T2 may receive a first gate signal GW. The first electrode of the second transistor T2 may receive the data voltage VDATA. The second electrode of the second transistor T2 may be connected to the second node N2.

The second transistor T2 may turn on or turn off in response to the first gate signal GW. While the second transistor T2 is turned on, the second transistor T2 may provide the data voltage VDATA to the second node N2. For example, the second transistor T2 may be referred to as a writing transistor.

The third transistor T3 may include a gate electrode, a first electrode, and a second electrode. The gate electrode of the third transistor T3 may receive a second gate signal GC. The first electrode of the third transistor T3 may be connected to the first node N1. The second electrode of the third transistor T3 may be connected to the third node N3.

The third transistor T3 may be turned on or turned off in response to the second gate signal GC. While the third transistor T3 is turned on, the third transistor T3 may diode-connect the first transistor T1. That is, the third transistor T3 may form a path to compensate a threshold voltage of the first transistor T1. For example, the third transistor T3 may be referred to as a compensation transistor.

The fourth transistor T4 may include a gate electrode, a first electrode, and a second electrode. The gate electrode of the fourth transistor T4 may receive a third gate signal GI. The first electrode of the fourth transistor T4 may be connected to the first node N1. The second electrode of the fourth transistor T4 may receive the first initialization voltage VINT through the third voltage line VL3.

The fourth transistor T4 may be turned on or turned off in response to the third gate signal GI. While the fourth transistor T4 is turned on, the fourth transistor T4 may provide the first initialization voltage VINT to the first node N1. Accordingly, the fourth transistor T4 may provide the first initialization voltage VINT to the gate electrode of the first transistor T1 to initialize a voltage of the gate electrode of the first transistor T1. For example, the fourth transistor T4 may be referred to as a gate initialization transistor.

The fifth transistor T5 may include a gate electrode, a first electrode, and a second electrode. The gate electrode of the fifth transistor T5 may receive an emission control signal EM. The first electrode of the fifth transistor T5 may receive the driving voltage ELVDD through the first voltage line VL1. The second electrode of the fifth transistor T5 may be connected to the second node N2.

The fifth transistor T5 may be turned on or turned off in response to the emission control signal EM. While the fifth transistor T5 is turned on, the fifth transistor T5 may provide the driving voltage ELVDD to the second node N2. For example, the fifth transistor T5 may be referred to as an emission control transistor.

The sixth transistor T6 may include a gate electrode, a first electrode, and a second electrode. The gate electrode of the sixth transistor T6 may receive the emission control signal EM. The first electrode of the sixth transistor T6 may be connected to the third node N3. The second electrode of the sixth transistor T6 may be connected to a fourth node N4.

The sixth transistor T6 may be turned on or turned off in response to the emission control signal EM. While the sixth transistor T6 is turned on, the sixth transistor T6 may electrically connect the second electrode of the first transistor T1 and an anode of the light-emitting element LD. Accordingly, the sixth transistor T6 may provide the driving current to the light-emitting element LD. For example, the sixth transistor T6 may be referred to as an emission control transistor.

Although the fifth transistor T5 and the sixth transistor T6 are illustrated in FIG. 3 as being simultaneously driven by the substantially single emission control signal EM, the present disclosure is not necessarily limited thereto. For example, the fifth transistor T5 and the sixth transistor T6 may be driven independently by different emission control signals.

The seventh transistor T7 may include a gate electrode, a first electrode, and a second electrode. The gate electrode of the seventh transistor T7 may receive a fourth gate signal GB. The first electrode of the seventh transistor T7 may receive the second initialization voltage VAINT through the fourth voltage line VL4. The second electrode of the seventh transistor T7 may be connected to the fourth node N4.

The seventh transistor T7 may be turned on or turned off in response to the fourth gate signal GB. While the seventh transistor T7 is turned on, the seventh transistor T7 may provide the second initialization voltage VAINT to the fourth node N4. Accordingly, the seventh transistor T7 may provide the second initialization voltage VAINT to the anode of the light-emitting element LD to initialize a voltage of the anode. For example, the seventh transistor T7 may be referred to as an anode initialization transistor.

The first capacitor C1 may include a first electrode and a second electrode. The first electrode of the first capacitor C1 may receive the driving voltage ELVDD through the first voltage line VL1. The second electrode of the first capacitor C1 may be connected to the first node N1. For example, the first capacitor C1 may be referred to as a storage capacitor.

The light-emitting element LD may include the anode and a cathode. The anode of the light-emitting element LD may be connected to the fourth node N4. The cathode of the light-emitting element LD may receive the common voltage ELVSS having a relatively low voltage level through the second voltage line VL2. That is, a voltage level of the common voltage ELVSS may be lower than a voltage level of the driving voltage ELVDD. The light-emitting element LD may generate light having a luminance corresponding to the driving current.

In FIG. 3, the pixel driving circuit PC is illustrated as including seven transistors and one capacitor, but the present disclosure is not necessarily limited thereto.

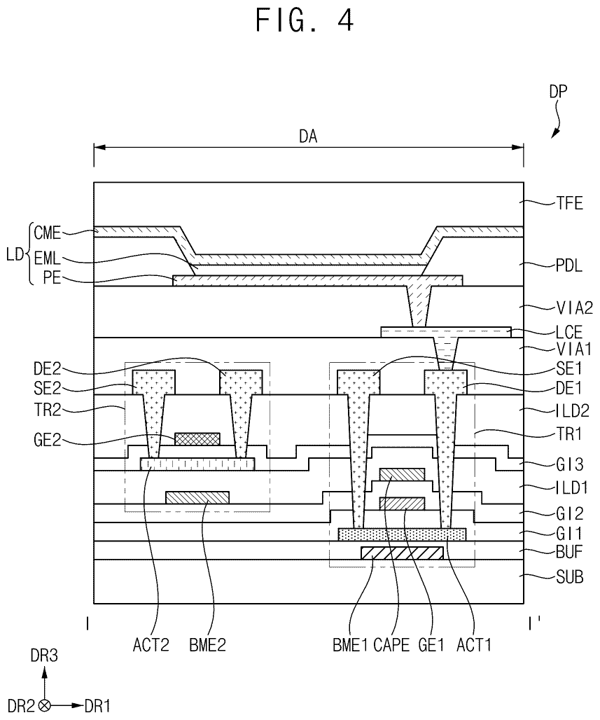

FIG. 4 is a cross-sectional view taken along the line I-I′ of FIG. 2.

Referring to FIG. 4, the display panel DP may include the substrate SUB, a buffer layer BUF, a first thin film transistor TR1, a first gate insulating layer GI1, a second gate insulating layer GI2, a capacitor electrode CAPE, a second thin film transistor TR2, a first inter-layer insulating layer ILD1, a second inter-layer insulating layer ILD2, a first via-insulating layer VIA1, a light-emitting element connection electrode LCE, a second via-insulating layer VIA2, the light-emitting element LD, a pixel defining layer PDL, and an encapsulation layer TFE.

The first thin film transistor TR1 may include a first lower electrode BME1, a first active pattern ACT1, a first gate electrode GE1, a first source electrode SE1, and a first drain electrode DE1. The second thin film transistor TR2 may include a second lower electrode BME2, a second active pattern ACT2, a second gate electrode GE2, a second source electrode SE2, and a second drain electrode DE2. The light-emitting element LD may include a pixel electrode PE, a light-emitting layer EML, and a common electrode CME.

The first thin-film transistor TR1 of FIG. 4 may be a transistor that is connected to the light-emitting element LD through the light-emitting element connection electrode LCE. For example, the first thin film transistor TR1 may be the sixth transistor T6 of FIG. 3, and the second thin film transistor TR2 may be any one of the third transistor T3 and the fourth transistor T4 of FIG. 3.

The first lower electrode BME1 may be disposed on the substrate SUB. The first lower electrode BME1 may overlap the first active pattern ACT1 in a plan view. The first lower electrode BME1 may include a conductive material such as a metal, an alloy, a conductive metal nitride, a conductive metal oxide, a transparent conductive oxide, or the like. Examples of the conductive material that may be used as the first lower electrode BME1 may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The buffer layer BUF may be disposed on the substrate SUB. The buffer layer BUF may cover the first lower electrode BME1. The buffer layer BUF may prevent diffusion of metal atoms or impurities from the substrate SUB to an upper structure. In addition, the buffer layer BUF may improve the flatness of a surface of the substrate SUB when the surface of the substrate SUB is not uniform. The buffer layer BUF may include an inorganic insulating material. Examples of the inorganic insulating material that may be used as the buffer layer BUF may include silicon oxide (SiOₓ), silicon nitride (SiNₓ), silicon oxynitride (SiOₓN_{y}), or the like. These may be used alone or in combination with each other. In an embodiment, the buffer layer BUF may be omitted.

The first active pattern ACT1 may be disposed on the buffer layer BUF. The first active pattern ACT1 may include a semiconductor material. In an embodiment, the first active pattern ACT1 may include a silicon semiconductor material. Examples of the silicon semiconductor material that may be used as the first active pattern ACT1 may include amorphous silicon, polycrystalline silicon, or the like.

The first gate insulating layer GI1 may be disposed on the buffer layer BUF. The first gate insulating layer GI1 may cover the first active pattern ACT1. The first gate insulating layer GI1 may include an inorganic insulating material.

The first gate electrode GE1 may be disposed on the first gate insulating layer GI1. The first gate electrode GE1 may overlap the first active pattern ACT1 in a plan view. The first gate electrode GE1 may function as a gate electrode of the first thin film transistor TR1. The first gate electrode GE1 may include a conductive material such as a metal, an alloy, a conductive metal nitride, a conductive metal oxide, a transparent conductive oxide, or the like.

These may be used alone or in combination with each other.

The second gate insulating layer GI2 may be disposed on the first gate insulating layer GI1. The second gate insulating layer GI2 may cover the first gate electrode GE1. The second gate insulating layer GI2 may include an inorganic insulating material.

The capacitor electrode CAPE may be disposed on the second gate insulating layer GI2. The capacitor electrode CAPE may overlap the first gate electrode GE1 in a plan view. The capacitor electrode CAPE and the first gate electrode GE1 may form the first capacitor C1 of FIG. 3. The capacitor electrode CAPE may include a conductive material such as a metal, an alloy, a conductive metal nitride, a conductive metal oxide, a transparent conductive oxide, or the like. These may be used alone or in combination with each other.

The second lower electrode BME2 may be disposed on the second gate insulating layer GI2. The second lower electrode BME2 may overlap the second active pattern ACT2 in a plan view. The second lower electrode BME2 may include a conductive material such as a metal, an alloy, a conductive metal nitride, a conductive metal oxide, a transparent conductive oxide, or the like.

The first inter-layer insulating layer ILD1 may be disposed on the second gate insulating layer GI2. The first inter-layer insulating layer ILD1 may cover the capacitor electrode CAPE and the second lower electrode BME2. The first inter-layer insulating layer ILD1 may include an inorganic insulating material.

The second active pattern ACT2 may be disposed on the first inter-layer insulating layer ILD1. The second active pattern ACT2 may include a semiconductor material. In an embodiment, the second active pattern ACT2 may include an oxide semiconductor material. The oxide semiconductor material may include at least one oxide of indium (In), gallium (Ga), tin (Sn), zirconium (Zr), vanadium (V), hafnium (Hf), cadmium (Cd), germanium (Ge), chromium (Cr), titanium (Ti), and zinc (Zn).

The third gate insulating layer GI3 may be disposed on the first inter-layer insulating layer ILD1. The third gate insulating layer GI3 may cover the second active pattern ACT2. The third gate insulating layer GI3 may include an inorganic insulating material.

The second gate electrode GE2 may be disposed on the third gate insulating layer GI3. The second gate electrode GE2 may overlap the second active pattern ACT2 in a plan view. The second gate electrode GE2 may function as a gate electrode of the second thin film transistor TR2. The second gate electrode GE2 may include a conductive material such as a metal, an alloy, a conductive metal nitride, a conductive metal oxide, a transparent conductive oxide, or the like.

The second inter-layer insulating layer ILD2 may be disposed on the third gate insulating layer GI3. The second inter-layer insulating layer ILD2 may cover the second gate electrode GE2. The second inter-layer insulating layer ILD2 may include an inorganic insulating material.

The first source electrode SE1 and the first drain electrode DE1 may be disposed on the second inter-layer insulating layer ILD2. The first source electrode SE1 may be connected to the first active pattern ACT1 through a contact hole penetrating the first gate insulating layer GI1, the second gate insulating layer GI2, the first inter-layer insulating layer ILD1, the third gate insulating layer GI3, and the second inter-layer insulating layer ILD2. The first drain electrode DE1 may be connected to the first active pattern ACT1 through a contact hole penetrating the first gate insulating layer GI1, the second gate insulating layer GI2, the first inter-layer insulating layer ILD1, the third gate insulating layer GI3, and the second inter-layer insulating layer ILD2.

Accordingly, the first thin film transistor TR1 including the first lower electrode BME1, the first active pattern ACT1, the first gate electrode GE1, the first source electrode SE1, and the first drain electrode DE1 may be disposed on the substrate SUB.

The second source electrode SE2 and the second drain electrode DE2 may be disposed on the second inter-layer insulating layer ILD2. The second source electrode SE2 may be connected to the second active pattern ACT2 through a contact hole penetrating the third gate insulating layer GI3 and the second inter-layer insulating layer ILD2. The second drain electrode DE2 may be connected to the second active pattern ACT2 through a contact hole penetrating the third gate insulating layer GI3 and the second inter-layer insulating layer ILD2.

Accordingly, the second thin film transistor TR2 including the second lower electrode BME2, the second active pattern ACT2, the second gate electrode GE2, the second source electrode SE2, and the second drain electrode DE2 may be disposed on the second gate insulating layer GI2.

The first via-insulating layer VIA1 may be disposed on the second inter-layer insulating layer ILD2. The first via-insulating layer VIA1 may cover the first source electrode SE1, the first drain electrode DE1, the second source electrode SE2, and the second drain electrode DE2. The first via-insulating layer VIA1 may include an organic insulating material. Examples of the organic insulating material that may be used as the first via-insulating layer VIA1 may include a polyacryl-based resin, a polyimide-based resin, a polyamide-based resin, a siloxane-based resin, an acryl-based resin, an epoxy-based resin, or the like. These may be used alone or in combination with each other.

The light-emitting element connection electrode LCE may be disposed on the first via-insulating layer VIA1. The light-emitting element connection electrode LCE may be connected to the first source electrode SE1 or the first drain electrode DE1 through a contact hole penetrating the first via-insulating layer VIA1. Accordingly, the light-emitting element connection electrode LCE may electrically connect the first thin-film transistor TR1 and the light-emitting element LD. The light-emitting element connection electrode LCE may include a conductive material such as a metal, an alloy, a conductive metal nitride, a conductive metal oxide, a transparent conductive oxide, or the like.

The second via-insulating layer VIA2 may be disposed on the first via-insulating layer VIA1. The second via-insulating layer VIA2 may cover the light-emitting element connection electrode LCE. The second via-insulating layer VIA2 may include an organic insulating material.

The pixel electrode PE may be disposed on the second via-insulating layer VIA2. The pixel electrode PE may be connected to the light-emitting element connection electrode LCE through a contact hole penetrating the second via-insulating layer VIA2. The pixel electrode PE may include a conductive material such as a metal, an alloy, a conductive metal nitride, a conductive metal oxide, a transparent conductive oxide, or the like. For example, the pixel electrode PE may function as the anode of the light-emitting element LD of FIG. 3.

The pixel defining layer PDL may be disposed on the second via-insulating layer VIA2. The pixel defining layer PDL may cover an edge of the pixel electrode PE, and may define a pixel opening exposing an upper surface of the pixel electrode PE. The pixel defining layer PDL may include an organic insulating material and/or an inorganic insulating material.

The light-emitting layer EML may be disposed on the pixel electrode PE. The light-emitting layer EML may emit light having a specific color (e.g., red, green, or blue). In an embodiment, the light-emitting layer EML may include at least one of an organic light-emitting material and a quantum dot. For example, the light-emitting layer EML may have a single-layer structure including one light-emitting structure. However, the present disclosure is not necessarily limited thereto, and the light-emitting layer EML may have a tandem structure including a plurality of light-emitting structures are stacked.

The common electrode CME may be disposed on the pixel defining layer PDL and the light-emitting layer EML. The common electrode CME may cover the pixel defining layer PDL and the light-emitting layer EML. For example, the common electrode CME may be disposed along the profiles of the pixel defining layer PDL and the light-emitting layer EML with a substantially uniform thickness. The common electrode CME may include a conductive material such as a metal, an alloy, a conductive metal nitride, a conductive metal oxide, a transparent conductive oxide, or the like. For example, the common electrode CME may function as the cathode of the light-emitting element LD of FIG. 3.

Accordingly, the light-emitting element LD including the pixel electrode PE, the light-emitting layer EML, and the common electrode CME may be disposed on the second via-insulating layer VIA2.

The encapsulation layer TFE may be disposed on the common electrode CME. The encapsulation layer TFE may prevent impurities, moisture, or the like from penetrating into the light-emitting element LD from the outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), or the like. These may be used alone or in combination with each other. For example, the organic encapsulation layer may include a polymer cured material such as polyacrylate or the like.

FIG. 5 is an enlarged plan view of the area A of FIG. 2. For example, FIG. 5 is a plan view illustrating the bus line part BUL disposed in the peripheral area PA.

Referring to FIG. 5, the bus line part BUL may be disposed in the peripheral area PA adjacent to a lower side of the display area DA, and may extend in the first direction DR1. The bus line part BUL may include a plurality of bus lines to which a constant voltage is applied. In an embodiment, the bus line part BUL may include a first bus line BL1, a second bus line BL2, a third bus line BL3, a fourth bus line BL4, and a fifth bus line BL5. The driving voltage (ELVDD, see FIG. 3) may be applied to the first bus line BL1. The common voltage (ELVSS, see FIG. 3) may be applied to the second bus line BL2. The first initialization voltage (VINT, see FIG. 3) may be applied to the third bus line BL3. The second initialization voltage (VAINT, see FIG. 3) may be applied to the fourth bus line BL4 and the fifth bus line BL5. The first to fifth bus lines BL1, BL2, BL3, BL4, and BL5 may transmit the constant voltage to the pixels PX through bus connection lines. For example, the fourth bus line BL4 may transmit the second initialization voltage VAINT to the first sub-pixel included in each pixel PX, and the fifth bus line BL5 may transmit the second initialization voltage VAINT to the second sub-pixel and the third sub-pixel included in each pixel PX. The first sub-pixel may emit red light, the second sub-pixel may emit green light, and the third sub-pixel may emit blue light, but the present disclosure is not necessarily limited thereto.

Each of the first to fifth bus lines BL1, BL2, BL3, BL4, and BL5 may extend in the first direction DR1. The first to fifth bus lines BL1, BL2, BL3, BL4, and BL5 may be spaced apart from each other. For example, the first to fifth bus lines BL1, BL2, BL3, BL4, and BL5 may be spaced apart from each other in the second direction DR2. In an embodiment, the first to fifth bus lines BL1, BL2, BL3, BL4, and BL5 may be spaced apart from each other and arranged in an order of the first bus line BL1, the third bus line BL3, the fourth bus line BL4, the fifth bus line BL5, and the second bus line BL2 along an opposite direction of the second direction DR2. However, the present disclosure is not necessarily limited thereto, and the order in which the first to fifth bus lines BL1, BL2, BL3, BL4, and BL5 are arranged along the opposite direction of the second direction DR2 may be variously changed according to embodiments.

Although not illustrated in FIG. 5, each of the first to fifth bus lines BL1, BL2, BL3, BL4, and BL5 extending in the first direction DR1 at the lower side of the display area DA may extend along the corner portion DAc (see FIG. 2).

In an embodiment, the first to fifth bus lines BL1, BL2, BL3, BL4, and BL5 may be disposed in the same layer as each other. The first to fifth bus lines BL1, BL2, BL3, BL4, and BL5 may be disposed in the same layer as the first source electrode SE1 and the first drain electrode DE1 of FIG. 4. The first to fifth bus lines BL1, BL2, BL3, BL4, and BL5, the first source electrode SE1, and the first drain electrode DE1 may include the same material and may be formed through the same process.

In an embodiment, a width (e.g., a length in the second direction DR2) of each of the first bus line BL1 and the second bus line BL2 may be greater than a width of each of the third bus line BL3, the fourth bus line BL4, and the fifth bus line BL5. For example, the width of each of the first bus line BL1 and the second bus line BL2 may be about 100 micrometers, and the width of each of the third bus line BL3, the fourth bus line BL4, and the fifth bus line BL5 may be about 50 micrometers. However, the present disclosure is not necessarily limited thereto.

FIG. 6 is an enlarged plan view of the area B of FIG. 2. For example, FIG. 6 is a plan view illustrating the pixels PX disposed in an area adjacent to the first scan driver DRV1, the bus line part BUL, and the corner portion DAc. In FIG. 2, a structure in which the pixels PX disposed in an area adjacent to the corner portion DAc, which connects the first side DA-1 and the second side DA-2, are connected to the first scan driver DRV1 and the bus line part BUL may be substantially the same or symmetrical to a structure in which the pixels PX disposed in an area adjacent to the corner portion DAc, which connects the first side DA-1 and the fourth side DA-4, are connected to the second scan driver DRV2 and the bus line part BUL. Accordingly, descriptions of the structure in which the pixels PX disposed in the area adjacent to the corner portion DAc, which connects the first side DA-1 and the fourth side DA-4, are connected to the second scan driver DRV2 and the bus line part BUL are omitted.

Referring to FIGS. 2 and 6, the display device DD may further include scan connection lines SCL, bus connection lines BCL, data connection lines DCL, dummy lines DML, and dummy pixels DPX.

In an area adjacent to the corner portion DAc, the pixels PX may be arranged in a stepwise manner. That is, the pixels PX may be arranged in a stepwise manner corresponding to a rounded shape of the display area DA in a plan view. As the pixels PX are arranged in a stepwise manner, the number of rows and the number of columns in which the pixels PX are arranged may differ in the area adjacent to the corner portion DAc. That is, the number of rows of the pixels PX arranged at the corner portion DAc adjacent to the second side DA-2 may be greater than the number of rows of the pixels PX arranged at the corner portion DAc adjacent to the first side DA-1. In addition, the number of columns of the pixels PX arranged at the corner portion DAc adjacent to the second side DA-2 may be less than the number of columns of the pixels PX arranged at the corner portion DAc adjacent to the first side DA-1. For example, as illustrated in FIG. 6, the pixels PX may be arranged in a stepwise manner by two pixels PX along the first direction DR1 (or a row direction) and four pixels PX along the second direction DR2 (or a column direction). However, the present disclosure is not necessarily limited thereto, and the number of pixels PX arranged in a stepwise manner may be variously changed according to embodiments.

The first scan driver DRV1 may be disposed in the peripheral area PA adjacent to the left side of the display area DA. That is, the first scan driver DRV1 may be spaced apart from the corner portion DAc. An end of the first scan driver DRV1 may extend along the corner portion DAc. The end of the first scan driver DRV1 may have a rounded shape in a plan view. The first scan driver DRV1 may transmit a scan signal to the pixels PX through the scan connection lines SCL. In an embodiment, the scan signal may be any one of the first gate signal GW, the second gate signal GC, the third gate signal GI, the fourth gate signal GB, and the emission control signal EM of FIG. 3.

The bus line part BUL may be spaced apart from the corner portion DAc. An end of the bus line part BUL may extend along the corner portion DAc. That is, the end of the bus line part BUL may extend between the first scan driver DRV1 and the corner portion DAc in a plan view. In other words, the end of the bus line part BUL may extend between the first scan driver DRV1 and the pixels PX arranged in a stepwise manner along the corner portion DAc. The bus line part BUL may transmit a constant voltage to the pixels PX through the bus connection lines BCL. In an embodiment, the constant voltage may be any one of the driving voltage ELVDD, the common voltage ELVSS, the first initialization voltage VINT, and the second initialization voltage VAINT of FIG. 3.

The data connection lines DCL may partially overlap the bus line part BUL between the first scan driver DRV1 and the pixels PX in a plan view. The data connection line DCL may electrically connect the driving chip D-IC disposed in the pad area PDA and the data line DL disposed in the display area DA. Accordingly, the data connection line DCL may transmit the data voltage (VDATA, see FIG. 3) to the data line DL. For example, the data connection line DCL may be referred to as a fan-out line.

The dummy lines DML may be disposed in the peripheral area PA on the substrate SUB. Each of the dummy wiring lines DML may partially overlap the bus line part BUL between the first scan driver DRV1 and the pixels PX in a plan view. In addition, each of the dummy lines DML may partially overlap the scan connection line SCL in a plan view.

The dummy line DML may receive a constant voltage through the bus line part BUL. The constant voltage may be any one of the driving voltage ELVDD, the common voltage ELVSS, the first initialization voltage VINT, and the second initialization voltage VAINT of FIG. 3. For example, the dummy line DML may be electrically connected to the first bus line BL1 of FIG. 5 through a connection pattern, and may receive the driving voltage ELVDD from the first bus line BL1. For example, the dummy line DML may be electrically connected to the second bus line BL2 of FIG. 5 through a connection pattern, and may receive the common voltage ELVSS from the second bus line BL2. For example, the dummy line DML may be electrically connected to the third bus line BL3 of FIG. 5 through a connection pattern, and may receive the first initialization voltage VINT from the third bus line BL3. For example, the dummy line DML may be electrically connected to the fourth bus line BL4 of FIG. 5 through a connection pattern, and may receive the second initialization voltage VAINT from the fourth bus line BL4. For example, the dummy line DML may be electrically connected to the fifth bus line BL5 of FIG. 5 through a connection pattern, and may receive the second initialization voltage VAINT from the fifth bus line BL5.

In an embodiment, the dummy line DML may be spaced further apart from the corner portion DAc than the bus connection line BCL in a plan view. The dummy line DML may extend parallel to the second side DA-2 of the display area DA. For example, the dummy line DML may extend in the second direction DR2. The dummy line DML may be adjacent to the second side DA-2 of the display area DA in the first direction DR1. That is, the dummy line DML may be adjacent to a portion extending in a straight line among the edge DA-ED of the display area DA in the first direction DR1. A length of the dummy line DML (e.g., a length in the second direction DR2) may be greater than a length of the bus connection line BCL. That is, the length of the dummy line DML may be greater than a length of the bus connection line BCL disposed at the outermost edge of the corner portion DAc.

In an embodiment, the dummy line DML may be positioned closer to the first scan driver DRV1 than the bus connection line BCL in a plan view.

The dummy line DML may be adjacent to the dummy pixels DPX. For example, the dummy line DML may be adjacent to the dummy pixels DPX in the second direction DR2. The dummy pixels DPX may be formed in consideration of the process deviation that may occur in a manufacturing process of the display device DD. The dummy pixels DPX may include a pattern substantially identical or similar to contact holes and electrodes included in the pixels PX. Unlike the pixels PX, the dummy pixels DPX may not emit light.

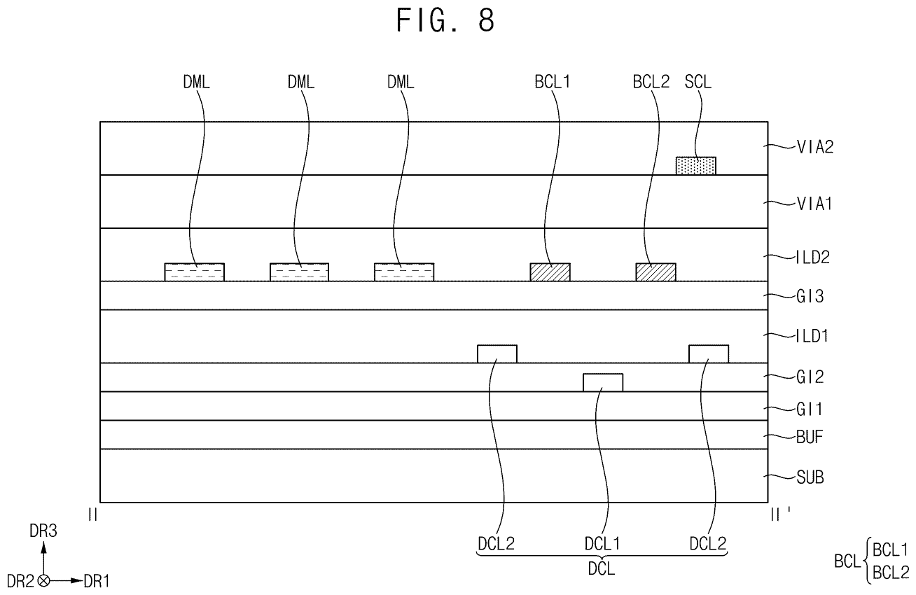

FIG. 7 is an enlarged plan view of the area C of FIG. 6. FIG. 8 is a cross-sectional view taken along the line II-IT′ of FIG. 7.

Referring to FIGS. 3, 6, 7, and 8, the display device DD may include a plurality of lines for transmitting scan signals and constant voltages to the pixels PX. For example, as illustrated in FIG. 7, the display device DD may include the scan line SL, a second voltage line VL2, a third voltage line VL3, and a fourth voltage line VL4 that are extending in a row direction (e.g., the first direction DR1) in the display area DA, and the data line DL extending in a column direction (e.g., the second direction DR2) in the display area DA.

The scan connection line SCL may electrically connect the first scan driver DRV1 disposed in the peripheral area PA and the scan line SL disposed in the display area DA. The scan connection line SCL may transmit the scan signal to the scan line SL. The scan signal may be any one of the first gate signal GW, the second gate signal GC, the third gate signal GI, the fourth gate signal GB, and the emission control signal EM. For example, the scan connection line SCL may be disposed in the same layer as the light-emitting element connection electrode LCE of FIG. 4. The scan connection line SCL and the light-emitting element connection electrode LCE may include the same material, and may be formed through the same process.

The scan line SL may receive the scan signal from the first scan driver DRV1 through the scan connection line SCL. The scan line SL may transmit the scan signal to the pixels PX. For example, the scan line SL may be disposed in the same layer as the first gate electrode GE1 of FIG. 4. The scan line SL and the first gate electrode GE1 may include the same material, and may be formed through the same process.

The bus connection line BCL may include a first bus connection line BCL1 and a second bus connection line BCL2 that are spaced apart from each other in a plan view. The first bus connection line BCL1 and the second bus connection line BCL2 may be disposed in the same layer as each other. For example, the first bus connection line BCL1 and the second bus connection line BCL2 may be disposed in the same layer as the second gate electrode GE2 of FIG. 4. The first bus connection line BCL1, the second bus connection line BCL2, and the second gate electrode GE2 may include the same material, and may be formed through the same process.

The first bus connection line BCL1 may be connected to the first bus line BL1 of FIG. 5. The first bus connection line BCL1 may receive the driving voltage ELVDD. The first bus connection line BCL1 may transmit the driving voltage ELVDD to the pixels PX. That is, although not illustrated in FIG. 7, the first bus connection line BCL1 may transmit the driving voltage ELVDD to the first voltage line VL1 of FIG. 3 through a connection pattern, and the first voltage line VL1 may transmit the driving voltage ELVDD to the pixels PX.

The second bus connection line BCL2 may be connected to the third bus line BL3 of FIG. 5. The second bus connection line BCL2 may receive the first initialization voltage VINT. The second bus connection line BCL2 may transmit the first initialization voltage VINT to the pixels PX. That is, although not illustrated in FIG. 7, the second bus connection line BCL2 may transmit the first initialization voltage VINT to the third voltage line VL3 through a connection pattern.

The third voltage line VL3 may receive the first initialization voltage VINT. That is, the third voltage line VL3 of FIG. 7 may correspond to the third voltage line VL3 of FIG. 3. The third voltage line VL3 may transmit the first initialization voltage VINT to the pixels PX. For example, the third voltage line VL3 may be disposed in the same layer as the capacitor electrode CAPE of FIG. 4. The third voltage line VL3 and the capacitor electrode CAPE may include the same material, and may be formed through the same process.

The second voltage line VL2 may be electrically connected to the second bus line BL2 of FIG. 5. The second voltage line VL2 may receive the common voltage ELVSS. That is, the second voltage line VL2 of FIG. 7 may correspond to the second voltage line VL2 of FIG. 3. The second voltage line VL2 may transmit the common voltage ELVSS to the pixels PX. For example, the second voltage line VL2 may be disposed in the same layer as the first source electrode SE1 and the first drain electrode DE1 of FIG. 4. The second voltage line VL2, the first source electrode SE1, and the first drain electrode DE1 may include the same material, and may be formed through the same process.

The fourth voltage line VL4 may be electrically connected to the fourth bus line BL4 or the fifth bus line BL5 of FIG. 5. The fourth voltage line VL4 may receive the second initialization voltage VAINT. That is, the fourth voltage line VL4 of FIG. 7 may correspond to the fourth voltage line VL4 of FIG. 3. The fourth voltage line VL4 may transmit the second initialization voltage VAINT to the pixels PX. For example, the fourth voltage line VL4 may be disposed in the same layer as the second gate electrode GE2 of FIG. 4. The fourth voltage line VL4 and the second gate electrode GE2 may include the same material, and may be formed through the same process.

In an embodiment, the scan line SL, the second voltage line VL2, the third voltage line VL3, and the fourth voltage line VL4 may be spaced apart from each other and arranged in an order of the scan line SL, the fourth voltage line VL4, the second voltage line VL2, and the third voltage line VL3 along the opposite direction of the second direction DR2. However, the present disclosure is not necessarily limited thereto.

The data connection line DCL may include a first data connection line DCL1 and a second data connection line DCL2 spaced apart from each other in a plan view. In an embodiment, the first data connection line DCL1 and the second data connection line DCL2 may be spaced apart from the first bus connection line BCL1 and the second bus connection line BCL2 in a plan view.

In an embodiment, as illustrated in FIG. 8, the first data connection line DCL1 and the second data connection line DCL2 may be disposed in different layers. In this case, the second data connection line DCL2 may be disposed on the first data connection line DCL1. For example, the first data connection line DCL1 may be disposed in the same layer as the first gate electrode GE1 of FIG. 4, and the second data connection line DCL2 may be disposed in the same layer as the capacitor electrode CAPE of FIG. 4. However, the present disclosure is not necessarily limited thereto.

In an embodiment, the first data connection line DCL1 and the second data connection line DCL2 may be disposed in the same layer as each other. For example, the first data connection line DCL1 and the second data connection line DCL2 may be disposed in the same layer as the first gate electrode GE1 of FIG. 4. For another example, the first data connection line DCL1 and the second data connection line DCL2 may be disposed in the same layer as the capacitor electrode CAPE of FIG. 4.

Each of the first data connection line DCL1 and the second data connection line DCL2 may electrically connect the driving chip (D-IC, see FIG. 2) and the data line DL. Each of the first data connection line DCL1 and the second data connection line DCL2 may transmit the data voltage VDATA to the data line DL. The data line DL may receive the data voltage VDATA through the first data connection line DCL1 or the second data connection line DCL2. The data line DL may transmit the data voltage VDATA to the pixels PX. For example, the data line DL may be disposed in the same layer as the light-emitting element connection electrode LCE of FIG. 4. The data line DL and the light-emitting element connection electrode LCE may include the same material, and may be formed through the same process.

In an embodiment, the data connection line DCL and the bus connection line BCL may be spaced apart from each other and arranged in an order of the second data connection line DCL2, the first bus connection line BCL1, the first data connection line DCL1, the second bus connection line BCL2, and the second data connection line DCL2 along the first direction DR1. However, the present disclosure is not necessarily limited thereto, and the order in which the data connection line DCL and the bus connection line BCL are arranged along the first direction DR1 may be variously changed according to embodiments.

The dummy line DML may extend parallel to the second side DA-2 of the display area DA. The dummy line DML may be adjacent to the second side DA-2 of the display area DA in the first direction DR1. The dummy line DML may be disposed in a different layer from the bus line part BUL and the scan connection line SCL. In an embodiment, the dummy line DML may be disposed under the first source electrode SE1 and the first drain electrode DE1 of FIG. 4.

For example, as illustrated in FIG. 8, the dummy line DML may be disposed in the same layer as the second gate electrode GE2 of FIG. 4. In this case, the dummy line DML, the second gate electrode GE2, the first bus connection line BCL1, and the second bus connection line BCL2 may be disposed in the same layer as each other. The dummy line DML, the second gate electrode GE2, the first bus connection line BCL1, and the second bus connection line BCL2 may include the same material, and may be formed through the same process. However, the present disclosure is not necessarily limited thereto.

For another example, the dummy line DML may be disposed in the same layer as the capacitor electrode CAPE in FIG. 4. In this case, the dummy line DML, the capacitor electrode CAPE, and the second data connection line DCL2 may be disposed in the same layer as each other. The dummy line DML, the capacitor electrode CAPE, and the second data connection line DCL2 may include the same material and may be formed through the same process.

For another example, the dummy line DML may be disposed in the same layer as the first gate electrode GE1 of FIG. 4. In this case, the dummy line DML, the first gate electrode GE1, and the first data connection line DCL1 may be disposed in the same layer as each other. The dummy line DML, the first gate electrode GE1, and the first data connection line DCL1 may include the same material, and may be formed through the same process.

An electrostatic discharge (ESD) may occur in the bus connection line BCL that transmits a constant voltage to the pixels PX. When the electrostatic discharge occurs in the bus connection line BCL adjacent to the corner portion DAc to transmit the constant voltage, a problem may occur in which a pulse potential due to the electrostatic discharge flows into the pixels PX adjacent to the corner portion DAc. For example, when the electrostatic discharge occurs in the first bus connection line BCL1 that transmits the driving voltage ELVDD, the pulse potential due to the electrostatic discharge may flow into the pixels PX through the third voltage line VL3. For another example, when the electrostatic discharge occurs in the first bus connection line BCL1 that transmits the driving voltage ELVDD, the pulse potential due to the electrostatic discharge may flow into the pixels PX through the second data connection line DCL2 and the third voltage line VL3. When the pulse potential due to the electrostatic discharge flows into the pixels PX, a malfunction of the pixel driving circuit PC included in the pixels PX may occur.

According to embodiments, the dummy line DML may be spaced further from the corner portion DAc than the bus connection line BCL in a plan view. The dummy line DML may extend parallel to the second side DA-2 of the display area DA, and may be adjacent to the second side DA-2 in the first direction DR1. The dummy line DML may induce a pulse potential caused by the electrostatic discharge generated in the bus connection line BCL to flow toward the dummy line DML. In other words, the pulse potential caused by the electrostatic discharge generated in the bus connection line BCL may flow into the dummy line DML, and the amount of the pulse potential flowing into the pixels PX may be reduced. Accordingly, the malfunction of the pixel driving circuit PC caused by the pulse potential may be reduced, and the display quality of the display device DD may be improved.

In addition, a length of the dummy line DML may be greater than a length of the bus connection line BCL. Accordingly, the line resistance of the dummy line DML may be greater than the line resistance of the bus connection line BCL, and the pulse potential may further flow into the dummy line DML, and the amount of the pulse potential flowing into the pixels PX may be further reduced.

FIG. 9 is a block diagram illustrating an electronic device according to an embodiment of the present disclosure.

Referring to FIG. 9, an electronic device 10 according to an embodiment may include a display module 11, a processor 12, a memory 13, and a power module 14. The display device according to an embodiment may be applied to a variety of electronic devices. The electronic device 10 according to an embodiment may include the display device described above, and may further include modules or devices having other additional functions in addition to the display device.

The processor 12 may include at least one of a central processing unit (CPU), an application processor (AP), a graphic processing unit (GPU), a communication processor (CP), an image signal processor (ISP), and a controller.

The memory 13 may store data information required for operation of the processor 12 or the display module 11. When the processor 12 executes an application stored in the memory 13, an image data signal and/or an input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power required for operation of the electronic device 10. That is, the power module 14 may provide power to the display device according to the embodiments described above.

At least one of the components of the electronic device 10 described above may be included in the display device according to the embodiments described above. In addition, some of the individual modules that are functionally included in one module may be included in the display device and others may be provided separately from the display device. For example, the display device may include the display module 11, and the processor 12, the memory 13, and the power module 14 may be provided in the form of other devices in the electronic device 10 other than the display device.

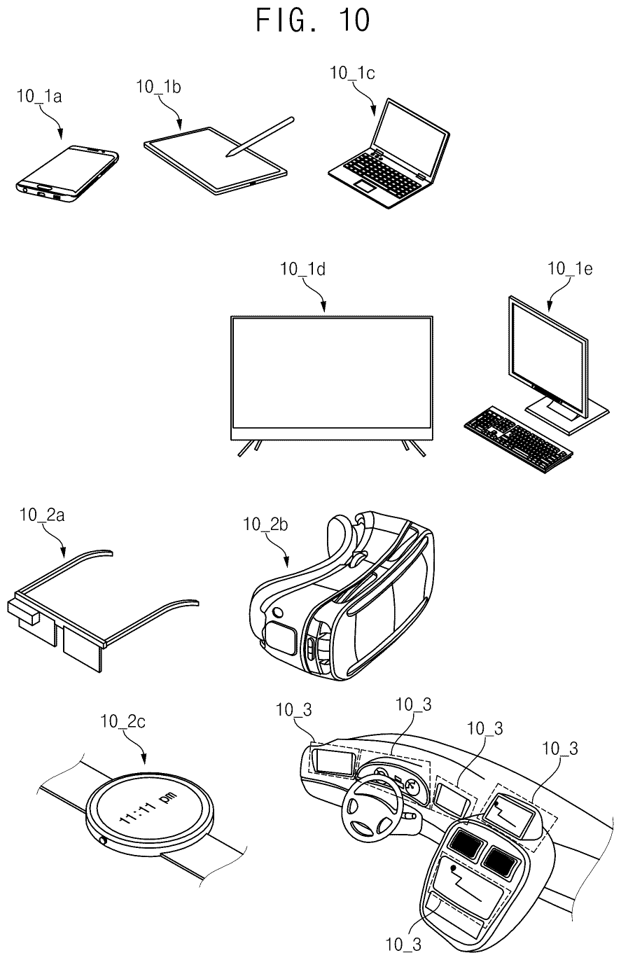

FIG. 10 is a schematic view of an electronic device according to various embodiments.

Referring to FIG. 10, various electronic devices to which a display device according to the embodiments is applied may include image display electronic devices such as a smartphones 10_1a, a tablet PC 10_1b, a laptop 10_1c, a television 10_1d, a desk monitor 10_1e, or the like, wearable electronic devices including display modules such as a smart glasses 10_2a, a head-mounted display 10_2b, and a smart watch 10_2c, or the like, and vehicle electronic devices 10_3 including display modules such as a CID (center information display) which may be disposed on a instrument panel, a center fascia, and a dashboard of an automobile and a room mirror display, or the like.

The present disclosure may be applied to various display devices. For example, the present disclosure is applicable to various display devices such as display devices for vehicles, ships and aircraft, portable communication devices, display devices for exhibition or information transmission, medical display devices, and the like.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A display device comprising:
a substrate comprising a display area and a peripheral area adjacent to the display area, the display area having an edge which comprises a corner portion having a rounded shape in a plan view;
a plurality of pixels in the display area on the substrate and arranged in a stepwise manner in an area adjacent to the corner portion;
a scan driver in the peripheral area on the substrate;
a bus line part in the peripheral area on the substrate, wherein the bus line part extends between the scan driver and the corner portion in the plan view, and the bus line part is configured to have a constant voltage applied thereto;
a bus connection line on the substrate, wherein the bus connection line is connected to the bus line part, the bus connection line is adjacent to the corner portion, and the bus connection line is configured to transmit the constant voltage to the plurality of pixels; and
a dummy line in the peripheral area on the substrate, wherein the dummy line is spaced further from the corner portion than the bus connection line in the plan view.

2. The display device of claim 1, wherein a length of the dummy line is greater than a length of the bus connection line.

3. The display device of claim 1, wherein
the edge of the display area further comprises a first side extending in a first direction and a second side extending in a second direction,
the second direction intersects the first direction, and
the corner portion connects the first side and the second side.

4. The display device of claim 3, wherein the dummy line extends parallel to the second side.

5. The display device of claim 3, wherein the dummy line is adjacent to the second side in the first direction.

6. The display device of claim 1, wherein the dummy line partially overlaps the bus line part in the plan view.

7. The display device of claim 1, further comprising:
a scan connection line on the substrate, wherein
the scan connection line is connected to the scan driver and the scan connection line is configured to transmit a scan signal to the plurality of pixels, and
wherein the dummy line partially overlaps the scan connection line in the plan view.

8. The display device of claim 1,
wherein the bus line part comprises a first bus line configured to have a driving voltage applied thereto,
the bus connection line comprises a first bus connection line,
the first bus connection line is connected to the first bus line, and
the first bus connection line is configured to transmit the driving voltage to the plurality of pixels.

9. The display device of claim 8, further comprising:
a first active pattern above the substrate;
a first gate electrode above the first active pattern;
a capacitor electrode above the first gate electrode;
a second gate electrode above the capacitor electrode; and
a source electrode and a drain electrode above the first active pattern.

10. The display device of claim 9, wherein the dummy line is under the source electrode and the drain electrode.

11. The display device of claim 10, wherein the dummy line and the second gate electrode are in a same layer.

12. The display device of claim 10, wherein the first bus line, the source electrode, and the drain electrode are in a same layer, and
wherein the first bus connection line and the second gate electrode are in a same layer.

13. A display device comprising:
a substrate comprising a display area and a peripheral area adjacent to the display area,
the display area having an edge which comprises a first side extending in a first direction, a second side extending in a second direction, and a corner portion which connects the first side and the second side and has a rounded shape in a plan view, the second direction intersecting the first direction;
a plurality of pixels in the display area on the substrate and arranged in a stepwise manner in an area adjacent to the corner portion;
a scan driver in the peripheral area on the substrate;
a bus line part in the peripheral area on the substrate, wherein the bus line part extends between the scan driver and the corner portion in the plan view, and the bus line part is configured to have a constant voltage applied thereto;
a bus connection line on the substrate, wherein the bus connection line is connected to the bus line part, the bus connection line extends in the second direction, and the bus connection line is configured to transmit the constant voltage to the plurality of pixels; and
a dummy line in the peripheral area on the substrate and positioned closer to the scan driver than the bus connection line in the plan view.

14. The display device of claim 13, wherein a length of the dummy line is greater than a length of the bus connection line.

15. The display device of claim 13, wherein the dummy line is adjacent to the second side in the first direction.

16. The display device of claim 13, wherein the bus connection line is adjacent to the corner portion and the bus connection line is configured to transmit the constant voltage to the plurality of pixels arranged in the stepwise manner in the area adjacent to the corner portion.

17. The display device of claim 13, wherein the dummy line partially overlaps the bus line part in the plan view.

18. The display device of claim 13, further comprising:
a scan connection line on the substrate, wherein
the scan connection line is connected to the scan driver and the scan connection line is configured to transmit a scan signal to the plurality of pixels, and
wherein the dummy line partially overlaps the scan connection line in the plan view.

19. The display device of claim 13,
wherein the bus line part comprises a first bus line configured to have a driving voltage applied thereto, and
the bus connection line comprises a first bus connection line,
the first bus connection line is connected to the first bus line, and
the first bus connection line is configured to transmit the driving voltage to the plurality of pixels.

20. An electronic device comprising:
a display device comprising a plurality of pixels; and
a processor configured to transmit an image data signal and an input control signal to the display device, wherein
the display device comprises a substrate, the plurality of pixels, a scan driver, a bus line part, a bus connection line, and a dummy line,
the substrate comprises a display area and a peripheral area adjacent to the display area,
the display area has an edge which comprises a corner portion having a rounded shape in a plan view,
the plurality of pixels are in the display area on the substrate and arranged in a stepwise manner in an area adjacent to the corner portion,
the scan driver is in the peripheral area on the substrate,
the bus line part is in the peripheral area on the substrate,
the bus line part extends between the scan driver and the corner portion in the plan view,
the bus line part is configured to have a constant voltage applied thereto,
the bus connection line is on the substrate,
the bus connection line is connected to the bus line part,
the bus connection line is adjacent to the corner portion,
the bus connection line is configured to transmit the constant voltage to the plurality of pixels,
the dummy line is in the peripheral area on the substrate, and
the dummy line is spaced further from the corner portion than the bus connection line in the plan view.
